(19) United States
(12) Patent Application Publication
(10) Pub. No.: US 2007/0247183 A1
(43) Pub. Date: Oct. 25, 2007

(54) LOGIC-LATCHING APPARATUS FOR IMPROVING SYSTEM-LEVEL ELECTROSTATIC DISCHARGE ROBUSTNESS

(76) Inventors: Chyh-Yih Chang, Taipei County (TW); Ching-Hua Huang, Tainan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,823

(22) Filed: May 11, 2006

(30) Foreign Application Priority Data
Mar. 16, 2006 (TW) 95108953

(51) Int. Cl. H03K 19/003

(52) U.S. Cl. 326/26

(57) ABSTRACT

A logic-latching apparatus includes a noise-event detection unit, a combinational logic unit and a latch unit. The noise-event detection unit is used for detecting whether or not a noise-event occurs (for example, an ESD). The latch unit is coupled with the noise-event detection unit and the combinational logic unit for latching the state of the combinational logic unit. When the output of the noise-event detection unit indicates that a noise-event occurs, the latch unit provides the input terminal of the combinational logic unit with a corresponding input signal according to the latched state of the combinational logic unit inside the latch unit to prevent the state of the combinational logic unit from being affected by the noise-event.

### CROSS-REFERENCE TO RELATED APPLICATION

This application claims the priority benefit of Taiwan application serial no. 95108953, filed on Mar. 16, 2006. All disclosure of the Taiwan application is incorporated herein by reference.

### BACKGROUND OF THE INVENTION

1. Field of Invention

The present invention relates to a logic-latching apparatus, and more particularly to a logic-latching apparatus for improving system-level noise-event (for example, electrostatic discharge) robustness.

2. Description of the Related Art

An electronic product used in real surroundings usually suffers various noise-event impacts, for example, electrostatic discharge (ESD) or electromagnetic interference (EMI). If there is no appropriate measure taken to provide protection, a noise-event is likely to damage the internal components of the electronic product. In particular, during an operation thereof, a noise-event probably causes the electronic product to a fatal failure, or even burns down the internal components thereof. To avoid the above-mentioned accidents, a system is usually equipped with a protection circuit by design to deal with various noise-events; for example, by means of an ESD protection circuit, the electrostatic current is induced into a power-rail.

In U.S. Pat. No. 5,237,395, an ESD protection circuit for protecting power-rails is disclosed, while U.S. Pat. No. 5,237,395 provides another ESD protection circuit for protecting power-rails. All these conventional schemes are to manage to prolong the time for sustaining an ESD zapping by using a detection circuit, which is started up to protect chips during an ESD. On the other hand, U.S. Pat. No. 6,658,597 develops a system-level ESD protection circuit for preventing a system from damage caused by a sequence difference to turn on powers or by an ESD zapping. The details of the above-mentioned prior arts are stated in the related patent specifications, thus they are omitted for simplicity.

During a normal operation, a noise-event likely affects the signal levels inside the system, which further leads to logic mistakes and consequently makes the system malfunction. International Electrotechnical Commission (IEC) has already framed several protection and testing standards focusing on electromagnetic compatibility (EMC) of commercial electronic apparatuses. In April 2001, for example, IEC published one of the protection and testing standards titled “Electromagnetic Compatibility (EMC)—Part 4-2: Testing and Measurement Techniques—Electrostatic Discharge Immunity Test”, or IEC.61000-4-2 in brief. According to the standard IEC.61000-4-2, the system logic states in an IC chip inside an electronic apparatus must keep unchanged and unaffected when an ESD occurs.

In the standard IEC.61000-4-2, the system-level testing environment is specified in detail, where a so-called system-level ‘A’ of ESD robustness means a system is required to be not affected by an ESD and to keep all the existing data. To achieve the goal, the system experiencing an ESD is required not only to keep the circuit stability thereof, but also to assure the received data in the internal circuits thereof unchanged.

When an ESD occurs, the internal circuits of the system may receive incorrect data twisted by a transient system voltage or a transient grounding voltage. FIG. 1 is a signal graph of a received data immediately after an ESD event occurs. The signal graph in the figure shows that the system is suffered by a surge current with a peak amplitude during the beginning 0.7˜1 ns and with a followed significant amplitude during at least 60 ns. So largely twisted signals of data received as an ESD event occurs certainly change the normal logic state of the data and result in a system failure. Therefore, a system must be assured that the data received by the internal circuits thereof are not affected by an ESD event.

### SUMMARY OF THE INVENTION

An objective of the present invention is to provide a logic-latching apparatus to prevent the data received by a combinational logic circuit from being affected by a noise-event (for example, ESD), so as to keep the original state of the received data and the normal system operation and to improve the system-level electrostatic discharge robustness.

Based on the above-mentioned or other objectives, the present invention provides a logic-latching apparatus, which includes a noise-event detection unit, a combinational logic unit and a latch unit. The noise-event detection unit is for detecting whether or not a noise-event occurs. The combinational logic unit includes at least an input terminal and at least an output terminal. The latch unit is coupled with the noise-event detection unit and the combinational logic unit for latching the state of the combinational logic unit. When an output from the noise-event detection unit indicates that a noise-event occurs, the latch unit provides the input terminal of the combinational logic unit with a corresponding input signal according to the latched state of the combinational logic unit inside the latch unit to prevent the state of the combinational logic unit from being affected by the noise-event.

According to the logic latch apparatus provided by an embodiment of the present invention, the above-described noise-event detection unit includes a resistor and a capacitor. The resistor and the capacitor are connected in series between a first power-rail and a second power-rail. Wherein, at the common connection point between the resistor and the capacitor, the detection result of the noise-event detection unit is output.

According to the logic latch apparatus provided by an embodiment of the present invention, the above-described noise-event detection unit includes multiple diodes. The diodes are connected in series between the first power-rail and the second power-rail, wherein at the cathode of one of the above-mentioned diodes, the detection result of the noise-event detection unit is output.

According to the logic latch apparatus provided by an embodiment of the present invention, the above-described latch unit includes a latch cell and a switch cell. The input terminal of the switch cell is coupled with the output terminal of the combinational logic unit. The latch cell outputs a corresponding signal at the output terminal thereof according to the output state of the combinational logic unit. The control terminal of the switch cell is coupled with the noise-event detection unit, while the first connection terminal and second connection terminal of the switch cell are respectively coupled with the output terminal of the latch cell and the input terminal of the combinational logic unit. When the output of the noise-event detection unit indicates that a noise-event occurs, the above-described switch cell would deliver the signal from the output terminal of the latch cell to the input terminal of the combinational logic unit.

Since the present invention employs a noise-event detection unit to detect a noise-event (an ESD, for example) and employs a latch unit to keep the voltage level at the input terminal of the combinational logic unit in the preceding logic state in response to a noise-event, thus, it is able to prevent the received data of the combinational logic circuit from being affected, so as to keep the normal system operation and to improve the system-level electrostatic discharge robustness.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve for explaining the principles of the invention.

FIG. 1 is a signal graph of a received data immediately after an ESD occurs.

FIG. 2 is a schematic drawing of an embodiment illustrating a logic-latching apparatus for improving system-level electrostatic discharge robustness according to the present invention.

FIG. 3 illustrates an embodiment of the logic-latching apparatus for improving system-level electrostatic discharge robustness in FIG. 2 used in an integrated circuit (IC) according to the present invention.

FIG. 4˜FIG. 6 are schematic drawings showing the other embodiments of the noise-event detection unit and the switch cell in FIG. 2 according to the present invention.

### DESCRIPTION OF THE EMBODIMENTS

The so-called “noise-event” generally refers to an event possibly affecting the normal operation of a system, such as ESD or EMI. For the convenience and clearness of describing the spirit of the present invention and the technical features thereof, only ESD is used as an example to explain the operation process of a logic-latching apparatus in response to a noise-event.

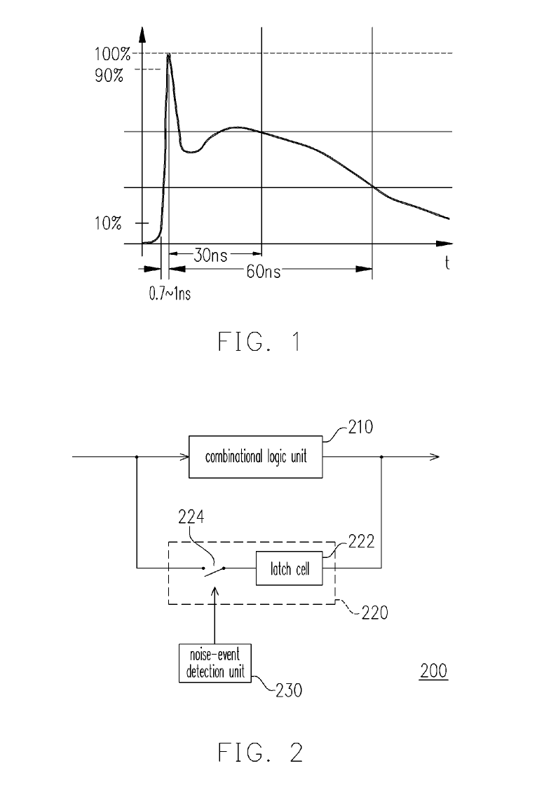

FIG. 2 is a schematic drawing of an embodiment for a logic-latching apparatus for improving system-level electrostatic discharge robustness according to the present invention. A logic-latching apparatus 200 includes a combinational logic unit 210, a latch unit 220 and a noise-event detection unit 230. The noise-event detection unit 230 is for detecting whether or not a noise-event, for example, an ESD event, occurs. The latch unit 220 is coupled with the noise-event detection unit 230 and the combinational logic unit 210 for latching the state of the combinational logic unit 210. When an output from the noise-event detection unit 230 indicates that a noise-event occurs, the latch unit 220 provides the input terminal of the combinational logic unit 210 with a corresponding input signal according to the latched state of the combinational logic unit 210 inside the latch unit to prevent the state of the combinational logic unit 210 from being affected by the noise-event.

In the present embodiment, the latch unit 220 includes a latch cell 222 and a switch cell 224. The input terminal of the switch cell 222 is coupled with the output terminal of the combinational logic unit 210 and the switch cell 222 is for providing a corresponding signal output at the output terminal thereof according to the output state of the combinational logic unit 210. The control terminal of the switch cell 224 is coupled with the noise-event detection unit 230, while the first connection terminal and second connection terminal of the switch cell 224 are respectively coupled with the output terminal of the latch cell 222 and the input terminal of the combinational logic unit 210. When the output of the noise-event detection unit signals that a noise-event occurs, the switch cell 224 would deliver the signal from the output terminal of the latch cell 222 to the input terminal of the combinational logic unit 210.

The combinational logic unit 210 herein can be a combinational logic unit of any level inside a system. When the system is in normal operation, the switch cell 224 is kept at a turnoff state by means of the control of the noise-event detection unit 230. Hence, during the normal operation, the combinational logic unit 210 of the logic-latching apparatus 200 receives signals from a pre-stage circuit (not shown). The received signals are processed by the combinational logic unit 210 and then sent to a next stage circuit (not shown). The latch cell 222 is able to latch the state of the combinational logic unit 210 anytime and provide a signal at the output terminal thereof corresponding to the state of the input terminal of the combinational logic unit 210.

When the system experiences an ESD impact, the signal at the input terminal of the combinational logic unit 210 may be in disorder. At the point, the noise-event detection unit 230 of the logic-latching apparatus 200 would turn on the switch cell 224 and the correct signals provided by the latch cell 222 is sent to the input terminal of the combinational logic unit 210. In this way, during an EDS occurs, the logic-latching apparatus 200 is able to keep the original correct input signals unaffected and thus abnormal operations of the system are avoided. Even after the EDS impact, the system is exempted from a system reset, which is supposedly to be conducted if the system is affected or damaged thereby. Therefore, a system equipped with the logic-latching apparatus 200 provided by the present invention meets the requirement of system-level ‘A’ of ESD robustness specified in the standard IEC.61000-4-2.

In the following, an integrated circuit (IC) equipped with a logic-latching apparatus provided by an embodiment of the present invention is described. The described case for an IC hereinafter is considered as exemplary only. Anyone skilled in the art is able to apply the present invention to any component for receiving data in a system to meet a specific requirement.

FIG. 3 illustrates an embodiment of the logic-latching apparatus 200 for improving system-level electrostatic discharge robustness in FIG. 2 used in an integrated circuit (IC) according to the present invention. Referring to FIG. 3, an IC 300 includes a bonding pad 310, an input buffer circuit 320 and an internal circuit 330. In the embodiment, the input buffer circuit 320 includes a Schmitt trigger circuit and can be implemented by using an appropriate scheme. The internal circuit 330 of the IC 300 receives external signals via the bonding pad 310 and the input buffer circuit 320. The internal circuit 330 includes a logic-latching apparatus and a next stage circuit 340, wherein the logic-latching apparatus includes a combinational logic unit 210, a noise-event detection unit 230, a latch cell 222 and a switch cell 224. In the embodiment, the combinational logic unit 210 of the logic-latching apparatus includes a NOT gate 331; the latch cell 222 includes a NOT gate 332; the switch cell 224 includes a NOT gate 333, a NOT gate 334 and a transmission gate 335; the noise-event detection unit 230 includes a resistor 336 and a capacitor 337.

In the embodiment, a system voltage VCC and a grounding voltage GND supplied by the outside of the IC 300 are provided to all the internal devices of the IC 300 via a first power-rail (for delivering the system voltage VCC) and a second power-rail (for delivering the grounding voltage GND). At the common connection point between the resistor 336 and the capacitor 337 (i.e. a node A), the detection result of the noise-event detection unit 230 is output. The voltages delivered by the first power-rail and the second power-rail are not limited to the above-mentioned designation, that is, the present invention can be applied to a power-rail pair with any voltage designation.

Under a normal system operation condition, the capacitor 337 in the noise-event detection unit 230 is fully charged, so as to keep the node A at a high-level (i.e. the level of the system voltage VCC). Accordingly, due to the high-level kept at the node A and buffered by the NOT-gates 333 and 334, the transmission gate 335 is turned off. Meanwhile, the output terminal of the NOT gate 332 stays in floating state and is not connected to the input terminal of the NOT gate 331, while the NOT gate 331 allows to receive the output signal from the input buffer circuit 320, followed by outputting a signal to the next stage circuit 340.

Because the system voltage VCC of the first power-rail and the grounding voltage GND of the second power-rail will be affected by the ESD, and further influence the output state of the input buffer circuit 320, the noise-event detection unit 230 of the present embodiment is used for detecting the level changes of the first power-rail and the second power-rail (i.e. the level changes of the system voltage VCC and the grounding voltage GND). Thanks to an RC time constant of the resistor 336 and capacitor 337 connected in series to each other in the noise-event detection unit 230, if the voltage levels of the system voltage VCC and the grounding voltage GND oscillate as an ESD occurs, the transient response behaviors of the resistor 336 and the capacitor 337 make the level at the node A far lower than the level of the first power-rail, that is, the level at the node A is considered as a logic low-level. Due to the logic low-level is kept at the node A and buffered by the NOT-gates 333 and 334, the transmission gate 335 is turned on. Thus, when the system experiences an ESD impact and the input signal of the combinational logic unit 210 is in disorder thereby, the internal circuit 330 can use the NOT gate 332 to keep the level at the input terminal of the NOT gate 331 in the correct logic state, which protects the input signal logic state of the IC 300 from being changed and thus sustains the normal operation of the system.

Note that to implement the combinational logic unit 210 and latch cell 222, the employed component is not limited to the above-described NOT-gate. In fact, the combinational logic unit 210 can be implemented by using any combinational logic component already existed in the system or a combination of multiple combinational logic components already existed in the system. Furthermore, the combinational logic unit 210 can be implemented by using an added combinational logic component or a combination of multiple added combinational logic components. The combinational logic unit 210 can further include, for example, a NOT-OR (NOR) gate, a NOT-AND (NAND) gate and a exclusive-OR (XOR) gate. In terms of the latch cell 222, anyone skilled in the art is able to select an appropriate component to implement it according to the function of the combinational logic unit 210. For example, if the output and the input of the combinational logic unit 210 are inverse-phased to each other by chance, a NOT gate is preferably used to implement the latch cell 222; alternatively, a NOR gate, a NAND gate or a XOR gate is taken as a NOT gate to implement the latch cell 222; alternatively, a latch can be used to implement the latch cell 222. On the other hand, if the output and the input of the combinational logic unit 210 are same-phased as each other by chance, a buffer is preferably used to implement the latch cell 222; alternatively, a NOR gate, a NAND gate or a XOR gate is taken as a buffer to implement the latch cell 222; alternatively, a latch can be used to implement the latch cell 222.

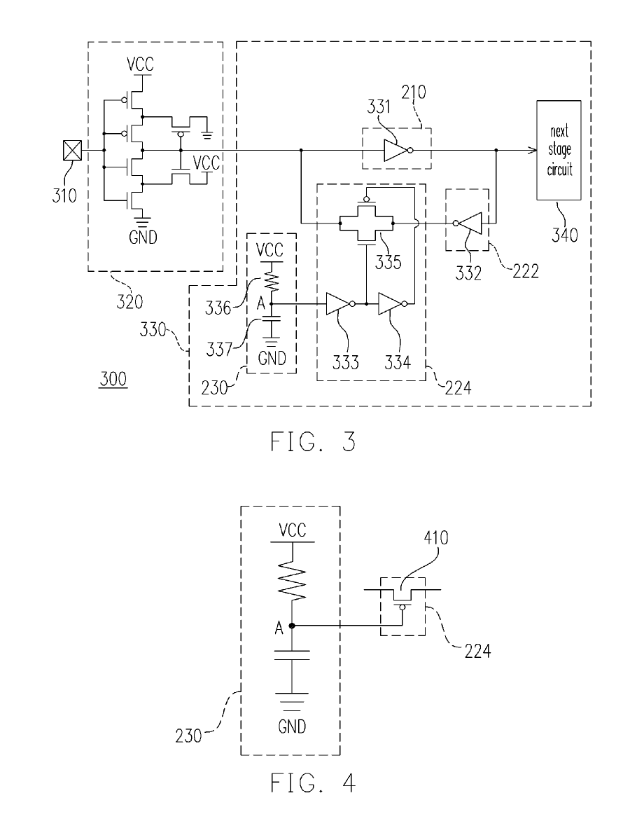

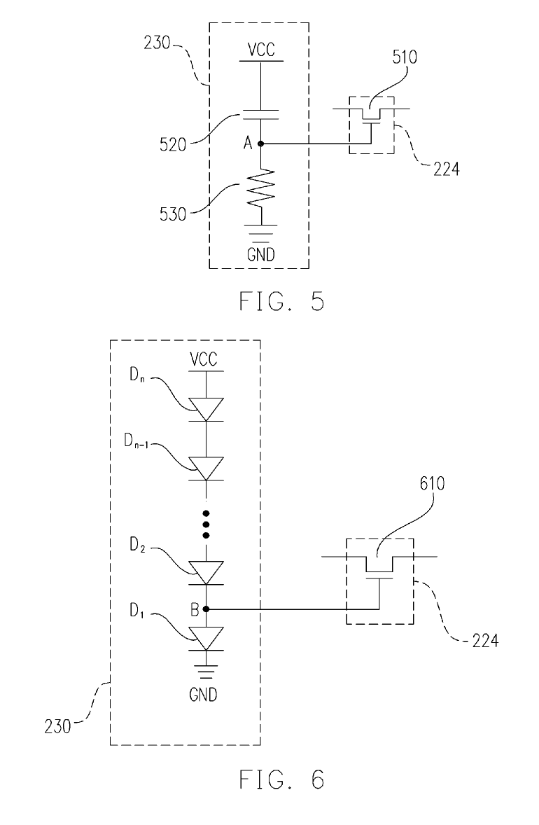

FIG. 4 is a schematic drawing showing another embodiment of the noise-event detection unit 230 and the switch cell 224 in FIG. 2 according to the present invention. The noise-event detection unit 230 in FIG. 4 is similar to that in FIG. 3 and the details are omitted herein for simplicity. Referring to FIG. 4, a switch cell 224 includes a P-type transistor 410. As the system is in normal operation, the node A is kept at a high-level and the P-type transistor 410 accordingly is at turnoff state by means of the control of the noise-event detection unit 230. As the system experiences an ESD impact, the voltage levels of the first power-rail and the second power-rail oscillate, which makes the level at the node A far lower than the level of the first power-rail, that is, the level at the node A is considered as a logic low-level. Thus, the transistor 410 is turned on.

FIG. 5 is a schematic drawing showing another embodiment of the noise-event detection unit 230 and the switch cell 224 in FIG. 2 according to the present invention. Referring to FIGS. 2 and 5, a switch cell 224 includes an N-type transistor 510, while the noise-event detection unit 230 includes a capacitor 520 and a resistor 530. The first terminal of the capacitor 520 is coupled with the first power-rail and the second terminal of the capacitor 520 is for outputting the detection result of the noise-event detection unit 230. The first end of the resistor 530 is coupled with the second terminal of the capacitor 520 and the second end of the resistor 530 is coupled with the second power-rail. The first power-rail is for delivering the system voltage VCC and the second power-rail is for delivering the grounding voltage GND.

Under a normal system operation condition, the capacitor 520 in the noise-event detection unit 230 is fully charged, so as to keep the node A at a low-level (i.e. the level of the grounding voltage GND). Accordingly, due to the low-level is kept at the node A, the transistor 510 is turned off. As the system experiences an ESD impact, because the levels of the system voltage VCC of the first power-rail and the grounding voltage GND of the second power-rail will be affected by ESD interference, the noise-event detection unit 230 of the present embodiment is used for detecting the level changes of the first power-rail and the second power-rail (i.e. the level changes of the system voltage VCC and the grounding voltage GND). Thanks to an RC time constant of the resistor 530 and capacitor 520 connected in series to each other in the noise-event detection unit 230, if the voltage levels of the system voltage VCC and the grounding voltage GND oscillate as an ESD occurs, the transient response behaviors of the resistor 530 and the capacitor 520 make the level at the node A far higher than the level of the second power-rail, that is, the level at the node A is considered as a logic high-level. Due to the logic high-level is kept at the node A, the transistor 510 is turned on. Thus, when the system experiences an ESD impact and the input signal of the combinational logic unit 210 is in disorder thereby, the logic-latching apparatus 200 can use the latch cell 222 to keep the level at the input terminal of the combinational logic unit 210 in the correct logic state, which protects the input signal logic state of the combinational logic unit 210 from being changed and sustains the normal operation of the system.

FIG. 6 is a schematic drawing showing another embodiment of the noise-event detection unit 230 and the switch cell 224 in FIG. 2 according to the present invention. Referring to FIGS. 2 and 6, a switch cell 224 includes an N-type transistor 610, while the noise-event detection unit 230 includes multiple diodes D₁˜Dₙ. The diodes D₁˜Dₙ are in series connected in forward bias manner between the first power-rail and the second power-rail, and the detection result of the noise-event detection unit 230 is output from the cathode (node B) of one of the diodes D₁˜Dₙ (for example, at the diode D₂ in the embodiment).

Under a normal system operation condition, since each of the diodes D₁˜Dₙ shares a partial voltage burden from the voltage difference between the system voltage VCC and the grounding voltage GND, therefore, a low-level is kept at the node A and the transistor 610 is accordingly turned off. As the system experiences an ESD impact, the ESD makes the system voltage VCC soar to a high-level, and the level at the node B also rises to a high-level therewith, which results in turning on the transistor 610. Thus, as the system experiences an ESD impact and the input signal of the combinational logic unit 210 is in disorder thereby, the logic-latching apparatus 200 can use the latch cell 222 to keep the level at the input terminal of the combinational logic unit 210 in the correct logic state, which protects the input signal logic state of the combinational logic unit 210 from being changed and sustains the normal operation of the system.

In summary, the present invention uses a noise-event detection unit for detecting a noise-event (for example, an ESD) and uses a latch unit to keep the level at the input terminal of the combinational logic unit thereof in the original logic state in response to a noise-event. Therefore, the present invention is able to prevent the received data of the combinational logic unit from being affected by the noise-event, keep the normal system operation and to improve the system-level electrostatic discharge robustness.

It will be apparent to those skilled in the art that various modifications and variations can be made to the structure of the present invention without departing from the scope or spirit of the invention. In view of the foregoing, it is intended that the specification and examples to be considered as exemplary only, with a true scope and spirit of the invention being indicated by the following claims and their equivalents.

What is claimed is:

1. A logic-latching apparatus, comprising:
a noise-event detection unit for detecting whether or not a noise-event occurs and outputting a detection result;
a combinational logic unit, comprising at least an input terminal and at least an output terminal; and
a latch unit coupled with the noise-event detection unit and the combinational logic unit for latching the state of the combinational logic unit, wherein when an output from the noise-event detection unit indicates that a noise-event occurs, the latch unit provides the input terminal of the combinational logic unit with a corresponding input signal according to the latched state of the combinational logic unit inside the latch unit to prevent the state of the combinational logic unit from being affected by the noise-event.

2. The logic-latching apparatus as recited in claim 1, wherein the noise-event comprises electrostatic discharge (ESD).

3. The logic-latching apparatus as recited in claim 1, wherein the noise-event detection unit comprises:
a resistor, wherein the first end thereof is coupled with a first power-rail, while the second end of the resistor outputs the detection result of the noise-event detection unit; and
a capacitor, wherein the first terminal thereof is coupled with the second end of the resistor, while the second terminal of the capacitor is coupled with a second power-rail.

4. The logic-latching apparatus as recited in claim 3, wherein the first power-rail is for supplying a system voltage, while the second power-rail supplies a grounding voltage.

5. The logic-latching apparatus as recited in claim 1, wherein the noise-event detection unit comprises:
a capacitor, wherein the first terminal thereof is coupled with a first power-rail, while the second terminal of the capacitor outputs the detection result of the noise-event detection unit; and
a resistor, wherein the first end thereof is coupled with the second terminal of the capacitor, while the second end of the resistor is coupled with a second power-rail.

6. The logic-latching apparatus as recited in claim 1, wherein the noise-event detection unit comprises:
a plurality of diodes in series connected in forward bias manner between a first power-rail and a second power-rail, wherein the cathode of one of the diodes outputs the detection result of the noise-event detection unit.

7. The logic-latching apparatus as recited in claim 1, wherein the combinational logic unit comprises a NOT gate.

8. The logic-latching apparatus as recited in claim 1, wherein the combinational logic unit comprises a NOR gate.

9. The logic-latching apparatus as recited in claim 1, wherein the combinational logic unit comprises a NOT-AND gate.

10. The logic-latching apparatus as recited in claim 1, wherein the combinational logic unit comprises an exclusive-OR gate.

11. The logic-latching apparatus as recited in claim 1, wherein the latch unit comprises:
a latch cell, wherein the input terminal thereof is coupled with the output terminal of the combinational logic unit for providing a corresponding signal from the output terminal of the latch cell according to the output state of the combinational logic unit; and
a switch cell, wherein the control terminal thereof is coupled with the noise-event detection unit, the first connection terminal and the second connection terminal of the switch cell are respectively coupled with the output terminal of the latch cell and the input terminal of the combinational logic unit, and, when an output of the noise-event detection unit indicates that a noise-event occurs, the switch cell delivers the signal from the output terminal of the latch cell to the input terminal of the combinational logic unit.

12. The logic-latching apparatus as recited in claim 11, wherein the latch cell comprises a NOT gate.

13. The logic-latching apparatus as recited in claim 11, wherein the latch cell comprises a NOR gate.

14. The logic-latching apparatus as recited in claim 11, wherein the latch cell comprises a NOT-AND gate.

15. The logic-latching apparatus as recited in claim 11, wherein the latch cell comprises a exclusive-OR gate.

16. The logic-latching apparatus as recited in claim 11, wherein the latch cell comprises a latch.

17. The logic-latching apparatus as recited in claim 11, wherein the switch cell comprises an N-type transistor.

18. The logic-latching apparatus as recited in claim 11, wherein the switch cell comprises a P-type transistor.

19. The logic-latching apparatus as recited in claim 11, wherein the switch cell comprises a transmission gate.
